(19) United States
(12) Patent Application Publication
(10) Pub. No.: US 2017/0025360 A1
(43) Pub. Date: Jan. 26, 2017

(54) SEMICONDUCTOR INTERCONNECT STRUCTURE AND MANUFACTURING METHOD THEREOF

(71) Applicant: National Tsing Hua University, Hsinchu City (TW)

(72) Inventors: Zheng-Yong Liang, Kaohsiung City (TW); Chao-Hui Yeh, Yunlin County (TW); Po-Wen Chiu, Hsinchu City (TW)

(21) Appl. No.: 14/849,605

(22) Filed: Sep. 10, 2015

(30) Foreign Application Priority Data
Jul. 23, 2015 (TW) 104123836

(51) Int. Cl. H01L 23/532; H01L 21/768; H01L 23/522

(52) U.S. Cl. CPC H01L 23/53238; H01L 23/5226; H01L 21/76802; H01L 21/76843; H01L 21/76877; H01L 21/7685

(57) ABSTRACT

A semiconductor interconnect structure and a manufacturing method thereof are provided. The semiconductor interconnect structure includes a barrier metal layer, a copper metal layer, and a compound thin film. The barrier metal layer is formed on an interconnect trench, the copper metal layer is formed on the barrier metal layer, and the compound thin film is formed on a surface of the copper metal layer, wherein the compound thin film contains organocopper and amorphous carbon. Therefore, the resulting semiconductor interconnect structure has reduced resistivity.

### CROSS-REFERENCE TO RELATED APPLICATION

This application claims the priority benefit of Taiwan application serial no. 104123836, filed on Jul. 23, 2015. The entirety of the above-mentioned patent application is hereby incorporated by reference herein and made a part of this specification.

### BACKGROUND OF THE INVENTION

Field of the Invention

The invention relates to a semiconductor interconnect technique, and more particularly, to a semiconductor interconnect structure and a manufacturing method thereof.

Description of Related Art

With the development of semiconductor device, the device size is getting smaller. Therefore, semiconductor interconnections have been developed into nano-generation. In current copper process, as the linewidth is reduced, interconnect resistance is rapidly increased due to boundary scattering and surface scattering. For instance, the bulk resistivity of copper is generally 1.68 μΩ·cm, but when the linewidth is reduced to 40 nm, the resistivity thereof reaches 5.0 μΩ·cm or greater. When the semiconductor interconnect is thinner, RC delay is greater, and the efficacy originally achieved by increasing density is nullified by the copper interconnect. Therefore, new semiconductor interconnect or improved versions of current semiconductor interconnect has been rigorously developed in recent years.

In recent years, researches about forming graphene on copper interconnects have been reported, and it is considered that such a structure facilitates the reduction of copper interconnect resistance. Therefore, current solutions for reducing interconnect resistivity are all related to increasing the thickness of the graphene layer or replacing a portion of the copper interconnect with graphene.

However, since the growth of graphene requires considering many parameters of the process, and copper interconnects or semiconductor devices below the copper interconnect may be damaged by high temperature during the growth of graphene, other solutions for reducing resistance of the semiconductor interconnects are urgently needed.

### SUMMARY OF THE INVENTION

The invention provides a semiconductor interconnect structure capable of reducing resistivity of the semiconductor interconnects and increasing current density of the semiconductor interconnects.

The invention further provides a semiconductor interconnect structure also capable of reducing resistivity of the semiconductor interconnects and increasing current density of the semiconductor interconnects.

The invention further provides a manufacturing method of a semiconductor interconnect structure capable of manufacturing a semiconductor interconnect having low resistivity and high current density.

The semiconductor interconnect structure of the invention includes a barrier metal layer, a copper metal layer, and a compound thin film. The barrier metal layer is formed on an interconnect trench, the copper metal layer is formed on the barrier metal layer, and the compound thin film is formed on a surface of the copper metal layer, wherein the compound thin film contains organocopper and amorphous carbon.

In an embodiment of the invention, the organocopper of the compound thin film is formed by a carbon source via a plasma process.

In an embodiment of the invention, the structure of the organocopper of the compound thin film is a compound containing carbon and hydrogen. Alternatively, the structure of the organocopper of the compound thin film is a compound containing carbon and copper bonds.

In an embodiment of the invention, the structure of the organocopper includes Cu—C₂H₂, Cu—CH₃, Cu—C, or a non-stoichiometric Cu—CₓH_{y}, wherein 0<x≦2 and 0≦y≦3.

In an embodiment of the invention, the copper metal layer is pure copper or a copper alloy.

In an embodiment of the invention, the amorphous carbon of the compound thin film can form a partially crystalline structure after a heat treatment.

In an embodiment of the invention, the thickness of the compound thin film is from several atomic layers to tens of nanometers.

In an embodiment of the invention, the semiconductor interconnect structure can further include a dielectric layer, wherein the interconnect trench is formed within the dielectric layer, the copper metal layer is located within the interconnect trench, the surface of the copper metal layer is exposed from the dielectric layer, and the compound thin film can be formed on the exposed surface of the copper metal layer.

In an embodiment of the invention, the semiconductor interconnect structure can further include a protective layer located on the compound thin film.

In an embodiment of the invention, the protective layer includes a metal layer, an insulation layer, or a combination thereof.

Another semiconductor interconnect structure of the invention includes a barrier metal layer, a first copper metal layer, and a composite layer. The barrier metal layer is formed on an interconnect trench, the first copper metal layer is formed on the barrier metal layer, and the composite layer is formed on a surface of the copper metal layer, wherein the composite layer is formed with alternating compound thin films and second copper metal layers, and each of the compound thin films contains organocopper and amorphous carbon.

The manufacturing method of a semiconductor interconnect structure of the invention includes first forming an interconnect trench structure, then forming a barrier metal layer on the interconnect trench structure, and then forming a copper metal layer on the barrier metal layer. Then, a compound thin film is grown on a surface of the copper metal layer via a plasma-enhanced chemical vapor deposition method, wherein the compound thin film contains organocopper and amorphous carbon.

In another embodiment of the invention, the substrate temperature for growing the compound thin film is set to about 450° C. or less.

In another embodiment of the invention, the reaction gas for growing the compound thin film includes a carbon-containing gas, a hydrogen gas, and an inert gas.

In another embodiment of the invention, the carbon-containing gas includes methane, ethylene, acetylene, or a combination thereof.

In another embodiment of the invention, the inert gas includes argon, helium, or a combination thereof.

In another embodiment of the invention, a hydrogen plasma pretreatment can be first performed on the copper metal layer before growing the compound thin film.

In another embodiment of the invention, annealing can be further performed in a hydrogen gas or a vacuum environment after growing the compound thin film.

In another embodiment of the invention, the temperature for performing annealing is 450° C. or less.

Based on the above, in the invention, according to the compound thin film containing organocopper and amorphous carbon growing on the surface of the copper metal layer, resistivity of the semiconductor interconnect structure can be reduced and current density of the semiconductor interconnect structure can be increased. Moreover, if a composite layer formed with alternating compound thin films and copper metal layers is on the surface of the copper metal layer, the resistivity of the semiconductor interconnect structure can also be reduced and current density of the semiconductor interconnect structure can also be increased.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic of a semiconductor interconnect structure according to the first embodiment of the invention.

FIG. 1B is a modified example of FIG. 1A.

FIG. 2 is a schematic of a semiconductor interconnect structure according to the second embodiment of the invention.

FIG. 3 shows steps of manufacturing a semiconductor interconnect structure according to the third embodiment of the invention.

FIG. 4 is a FTIR spectrum of the compound thin film of preparation example 1.

FIG. 5 is a graph of resistivity of experimental example 1 and comparative example 1 with different linewidth.

FIG. 6 is a graph of rate of change of resistance of experimental example 1 and comparative example 1 with different linewidth.

FIG. 7 is a graph of current density of experimental example 1 and comparative example 1 with different linewidth.

FIG. 8 is a graph of rate of change of current density of experimental example 1 and comparative example 1 with different linewidth.

FIG. 9 is a graph of resistivity of experimental example 1 and experimental example 2 with different linewidth.

FIG. 10 is a graph of linewidth against current density of experimental example 1 and experimental example 2.

### DESCRIPTION OF THE EMBODIMENTS

Embodiments with drawings are provided hereinafter to more completely describe the invention concept. However, many different forms can be used to implement the invention concept. Therefore, the invention should not be limited to the embodiments described in the specification; instead, the embodiments are used to make the invention clearer and more complete. In the drawings, common characteristics of the structures and/or methods used in specific embodiments are shown. However, they should not be interpreted to define or limit the scopes or the properties of the descriptions in the embodiments. For instance, for clarity, the relative thickness and location of films layers, regions, and/or structural devices may be reduced or enlarged.

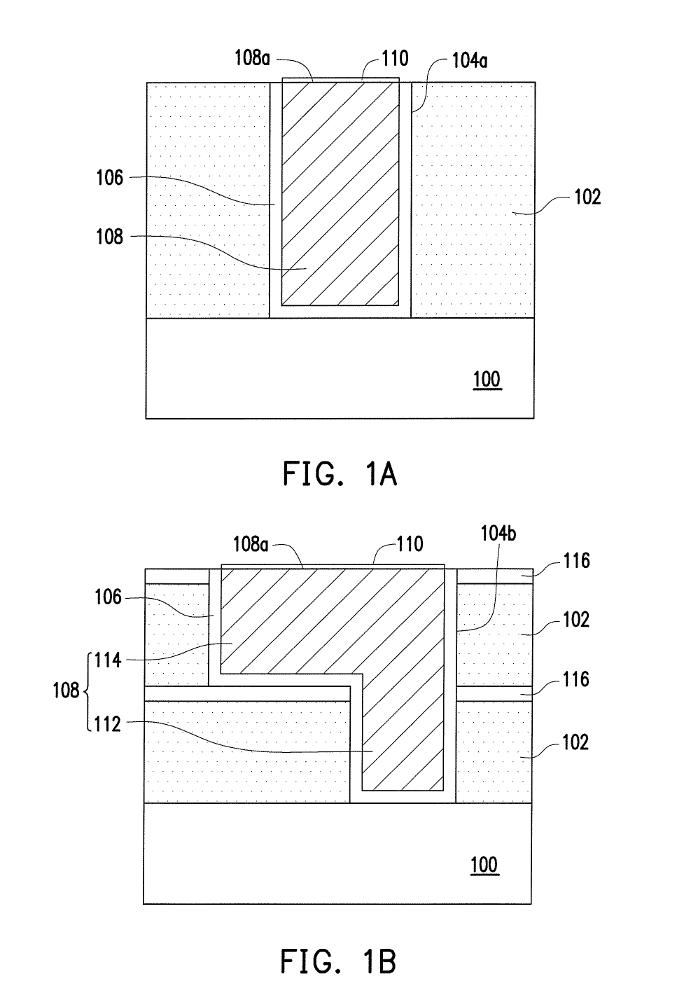

FIG. 1A is a schematic of a semiconductor interconnect structure according to the first embodiment of the invention.

Referring to FIG. 1A, the semiconductor interconnect structure of the present embodiment can be located on a substrate 100, and the substrate 100 is, for instance, a general semiconductor substrate or a semiconductor chip on which various semiconductor devices are formed. In an embodiment, a dielectric layer 102 is disposed on the substrate 100, and an interconnect trench 104a is formed in the dielectric layer 102. The dielectric layer 102 is, for instance, a low-k dielectric layer, etc. The interconnect trench 104a in FIG. 1A is a single trench, but it is not limited thereto; an interconnect trench 104b shown in FIG. 1B can also be a dual damascene trench.

Referring to both FIG. 1A and FIG. 1B, the semiconductor interconnect structure of the present embodiment includes a barrier metal layer 106, a copper metal layer 108, and a compound thin film 110. The barrier metal layer 106 is formed on the interconnect trenches 104a/104b, and may conformally cover the sides and the bottom surface of the interconnect trenches 104a/104b. The barrier metal layer 106 of the present embodiment can be a single-layer structure or a multi-layer structure. Moreover, although the barrier metal layer 106 in FIG. 1A is only displayed within the interconnect trench 104a, it is not limited thereto; the barrier metal layer 106 can also cover the top surface of the dielectric layer 102. Similarly, the barrier metal layer 106 in FIG. 1B can also cover the top surface of the dielectric layer 102. The copper metal layer 108 is formed on the barrier metal layer 106, and the copper metal layer 108 is, for instance, located within the interconnect trench 104a, and a surface 108a thereof is exposed from the dielectric layer 104a, wherein the copper metal layer 108 is, for instance, pure copper or a copper alloy. If the copper metal layer 108 is located in the interconnect trench 104b of FIG. 1B, the copper metal layer 108 can be formed with a via 112 for perpendicular connection and a contact pad 114 for horizontal connection, and a structure such as etch-stop layer 116 is between the dielectric layers 102.

The compound thin film 110 is formed on the exposed surface 108a of the copper metal layer 108, wherein the compound thin film 110 contains organocopper and amorphous carbon. For example, the organocopper is formed by a carbon source via a plasma process. The structure of the organocopper may be a compound containing hydrogen and carbon, and alternatively it may be a compound containing carbon and copper bonds. Accordingly, the structure of the organocopper, for instance, includes Cu—C₂H₂, Cu—CH₃, or Cu—C. In addition, due to plasma pyrolysis, non-stoichiometric organocopper may be formed, such as Cu—CₓH_{y} (wherein 0<x≦2; 0≦y≦3). The thickness of the compound thin film 110 is, for instance, from several atomic layers to tens of nanometers. Moreover, the outermost layer of the compound thin film 110 can be amorphous carbon. The amorphous carbon within the compound thin film 110 can form a partially crystalline structure after a heat treatment, wherein the heat treatment is, for instance, an annealing process. In an embodiment, a protective layer (not shown) can be further disposed on the compound thin film 110, wherein the protective layer may be a metal layer, an insulation layer, or a combination thereof for protecting the compound thin film 110 from oxidation or influence from the environment.

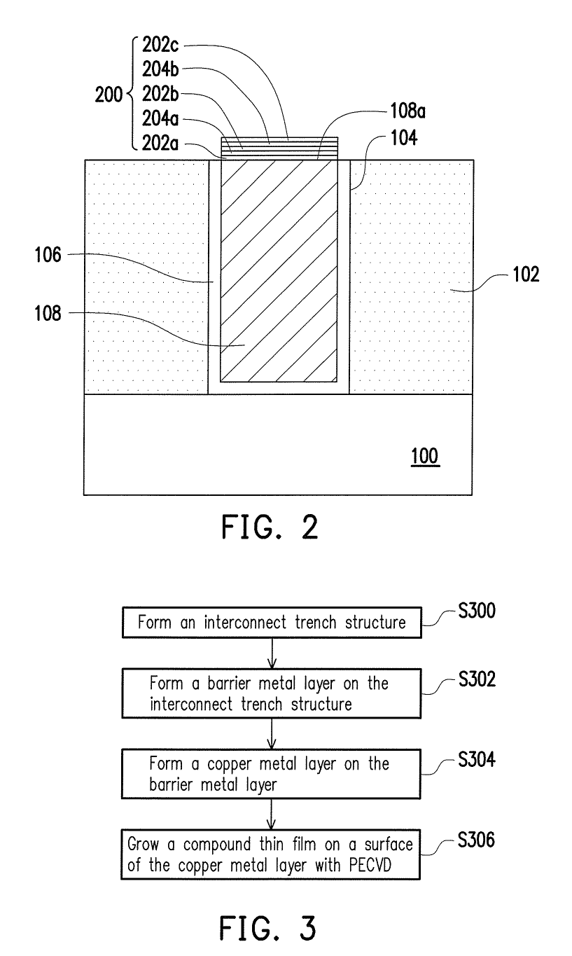

FIG. 2 is a schematic of a semiconductor interconnect structure according to the second embodiment of the invention, and the same reference numerals as the first embodiment are used in FIG. 2 to represent the same or similar components.

Referring to FIG. 2, the difference between the semiconductor interconnect structure of the present embodiment and that in the first embodiment is a composite layer 200. The composite layer 200 is formed on the surface 108a of the copper metal layer 108, and it is formed with alternating compound thin films 202a-c and second copper metal layers 204a-b, and all of the compound thin films 202a-c contain organocopper and amorphous carbon. Therefore, according to the composite layer 200, the resistivity of the semiconductor interconnect structure may be reduced and the current density of the semiconductor interconnect structure may be increased. The compound thin films 202a-c and the second compound thin films 204a-b are all as described for the compound thin film 110 and the copper metal layer 108 of the first embodiment, and are therefore not repeated herein.

FIG. 3 shows the steps of manufacturing a semiconductor interconnect structure according to the third embodiment of the invention.

Referring to FIG. 3, in step S300, an interconnect trench structure is formed and it can be designed to meet with different needs. For example, the interconnect trench structure may include the dielectric layer 102 located on the substrate 100 and the interconnect trench 104a formed in the dielectric layer 102 as shown in FIG. 1A. However, the invention is not limited thereto, and the interconnect trench structure in the third embodiment can be a structure having a dual damascene trench as shown in FIG. 1B.

Then, step S302 is performed to form a barrier metal layer on the interconnect trench structure, and the step of forming the barrier metal layer includes, for instance, conformally depositing a single barrier metal layer or a barrier metal layer consisted of multi-layer structure on the interconnect trench structure surface, and then optionally removing the barrier metal layer outside the interconnect trench in a subsequent process.

Then, step S304 is performed to form a copper metal layer on the barrier metal layer. The step of forming the copper metal layer is, for instance, a deposition or electroplating process. Moreover, after forming the copper metal layer, if extra copper metal is present outside the interconnect trench, a process such as CMP can be performed to remove unwanted copper metal layer outside the interconnect trench.

Then, step S306 is performed, in which a compound thin film is grown on a surface of the copper metal layer via a plasma-enhanced chemical vapor deposition (PECVD) method. The compound thin film contains organocopper and amorphous carbon. The organocopper is, for instance, formed by a carbon source via a plasma-enhanced chemical vapor deposition method, and the structure thereof can be a compound containing carbon and hydrogen, or the structure thereof can be a compound containing carbon and copper bonds. Accordingly, the structure of the organocopper, for instance, includes Cu—C₂H₂, Cu—CH₃, or Cu—C. Because of plasma pyrolysis, non-stoichiometric organocopper may be formed, such as Cu—CₓH_{y} (wherein 0<x≦2 and 0≦y≦3). The PECVD method is, for instance, an electron cyclotron resonance (ECR) PECVD or other suitable PECVD methods. In the present embodiment, the process time for growing the compound thin film is, for instance, less than 10 minutes, and the substrate temperature for growing the compound thin film is, for instance, set to 450° C. or less. Moreover, the reaction gas for growing the compound thin film includes, for instance, a carbon-containing gas, a hydrogen gas, and an inert gas, wherein the carbon-containing gas includes methane, ethylene, acetylene, or a combination thereof; and the inert gas includes argon, helium, or a combination thereof. Moreover, before step S306, a hydrogen (H₂) plasma pretreatment can be performed on the copper metal layer to remove native oxide or the like on the surface thereof.

After step S306, annealing may be further performed in a hydrogen gas or a vacuum environment to facilitate the amorphous carbon within the compound thin film to form a partially crystalline structure, so as to further reduce the resistivity of the semiconductor interconnect structure. The temperature for performing the annealing step is, for instance, 450° C. or less.

Several experiments are listed below to verify the effect of the invention. However, the scope of the invention is not limited to the following experiments.

### Preparation Example 1

A substrate was placed in an ECR plasma chemical vapor deposition machine, and the substrate was pre-heated to 400° C. and the pressure was kept at 2E-6 Torr. An interconnect trench, a barrier metal layer, and a copper metal layer as shown in FIG. 1B were formed within the substrate used in preparation example 1, and a photoresist polymer covered and preserved the substrate surface.

Then, a working distance of 5 cm was set, and Ar plasma was introduced to perform precleaning for about 1 minute to remove the polymer material on the substrate surface. At this point, the pressure was 5 mTorr, and the microwave power was 200 W. Then, H₂ plasma was introduced to perform a pretreatment for about 1 minute to remove oxide on the substrate surface at 2.5 mTorr, and the microwave power was 200 W.

Then, the substrate temperature was set to 400° C., ethylene (C₂H₄) and argon (Ar) were used as the reaction gas, and a compound thin film was grown under the conditions of a pressure of about 8 mTorr and a microwave power of about 1000 W, and the process time was variable, as shown in Table 1. Then, annealing was performed for 5 minutes in a H₂ environment, and the pressure was about 0.5 mTorr. Then, the resistance value of each of the preparation samples was measured, and the results are shown in the following Table 1.

TABLE 1

| Process time (minutes) | Rₛ (kΩ/□) |
|---|---|
| 4 | 18 |
| 3 | 28 |
| 2 | 43 |

The result that increased process time causes reduced resistance is obtained from Table 1.

Test 1

A Raman test was performed on the compound thin film of preparation example 1 (process time of about 2-4 minutes) to obtain the result that the compound thin film contains amorphous carbon.

Test 2

A compound thin film having a large area was grown using the method of preparation example 1, and an FTIR test was performed on the compound thin film to obtain the spectrum of FIG. 4. FIG. 4 shows absorption peaks respectively at 376 cm⁻¹, 507 cm⁻¹, and 609 cm⁻¹, and the compound corresponding to 376 cm⁻¹ is C₂H₂Cu, thus proving the compound thin film contains organocopper having the structure of Cu—C₂H₂. It should be mentioned that, when the compound forms non-stoichiometric organocopper, such as Cu—CₓH_{y}, wherein 0<x≦2 and 0≦y≦3, the absorption peaks of the FTIR absorption spectrum thereof are shifted, that is, the absorption peak may appear before or after several wavenumbers of the stoichiometric organocopper compound.

### Experimental Example 1

A compound thin film was grown on the surface of copper metal layers having different linewidths with the same steps as preparation example 1. The process time for growing the compound thin film in experimental example 1 was about 2-4 minutes.

### Comparative Example 1

A compound thin film was grown on the surface of copper metal layers having different linewidths using the same steps as preparation example 1, until the step in which H₂ plasma was introduced to perform pretreatment. Therefore, a compound thin film was absent in comparative example 1.

Test 3

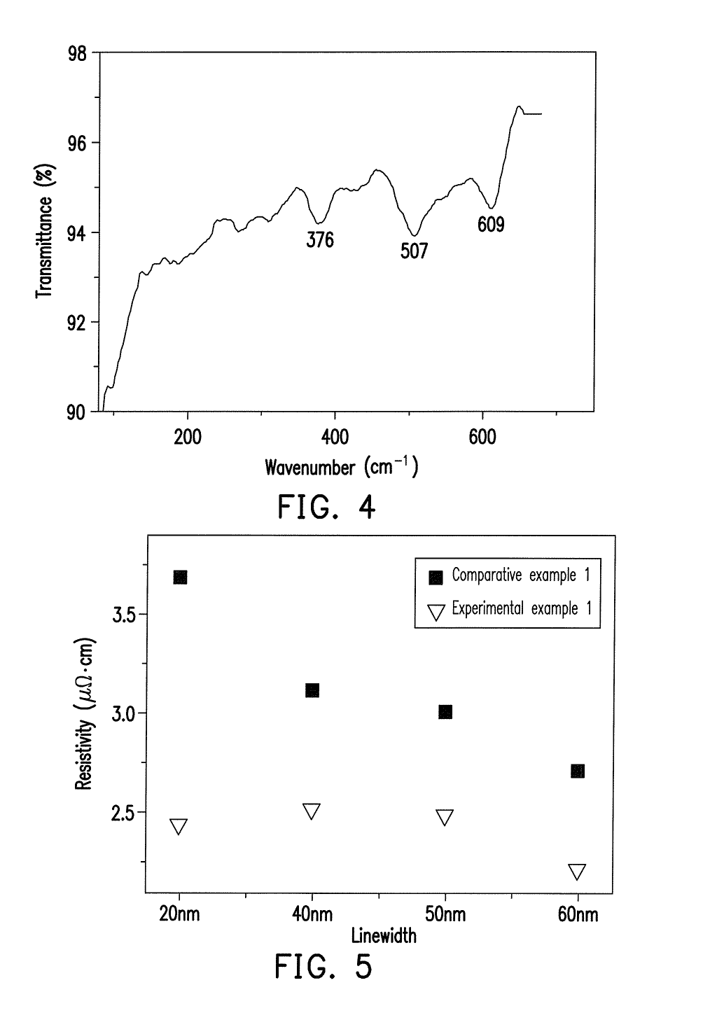

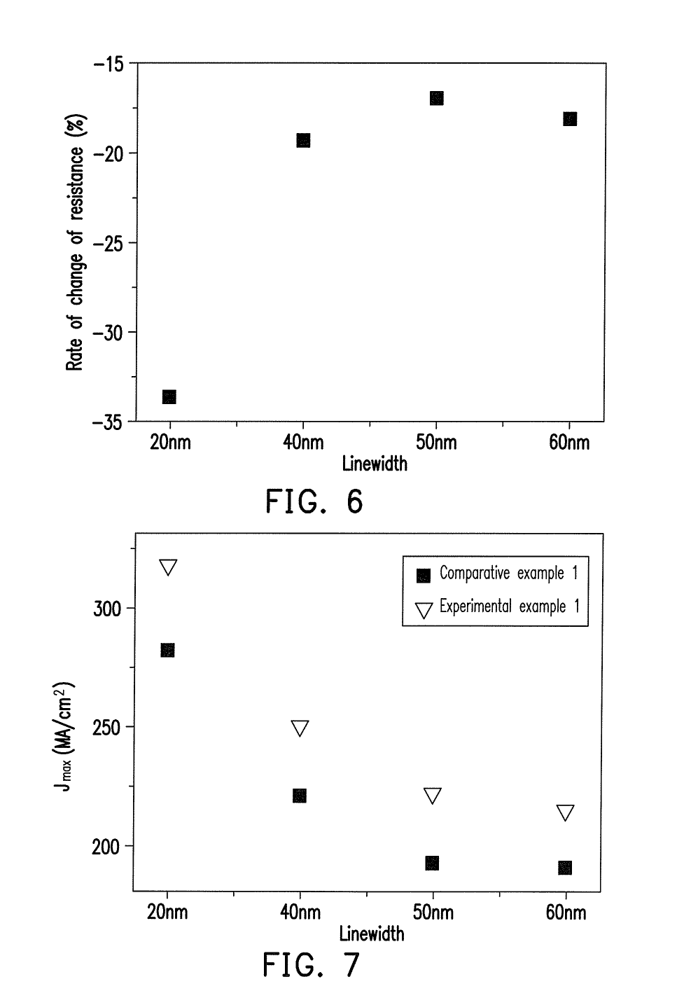

A resistivity test was repeatedly performed on the samples obtained in experimental example 1 and comparative example 1, and average values thereof were obtained. The results are shown in Table 2 and FIG. 5 below. At the same time, the rate of change of the difference in resistivity of experimental example 1 and comparative example 1 was calculated, and the results are shown in Table 2 and FIG. 6.

TABLE 2

| | | |
|---|---|---|
| | | Experimental |
| Comparative | Experimental | example 1 |
| example 1 | example 1 | Rate of change of |

| | | |
|---|---|---|
| Linewidth | Average resistivity (μΩ · cm) | resistance (%) |

| | | | |
|---|---|---|---|
| 20 nm | 3.7 | 2.5 | −33.6 |
| 40 nm | 3.1 | 2.5 | −19.2 |
| 50 nm | 3.0 | 2.5 | −16.9 |
| 60 nm | 2.7 | 2.2 | −18.1 |

It can be known from Table 2 and FIG. 6 that, at a linewidth of 20 nm to 60 nm, the resistivity of the semiconductor interconnect structures having the compound thin film is much lower than that without compound thin film.

Test 4

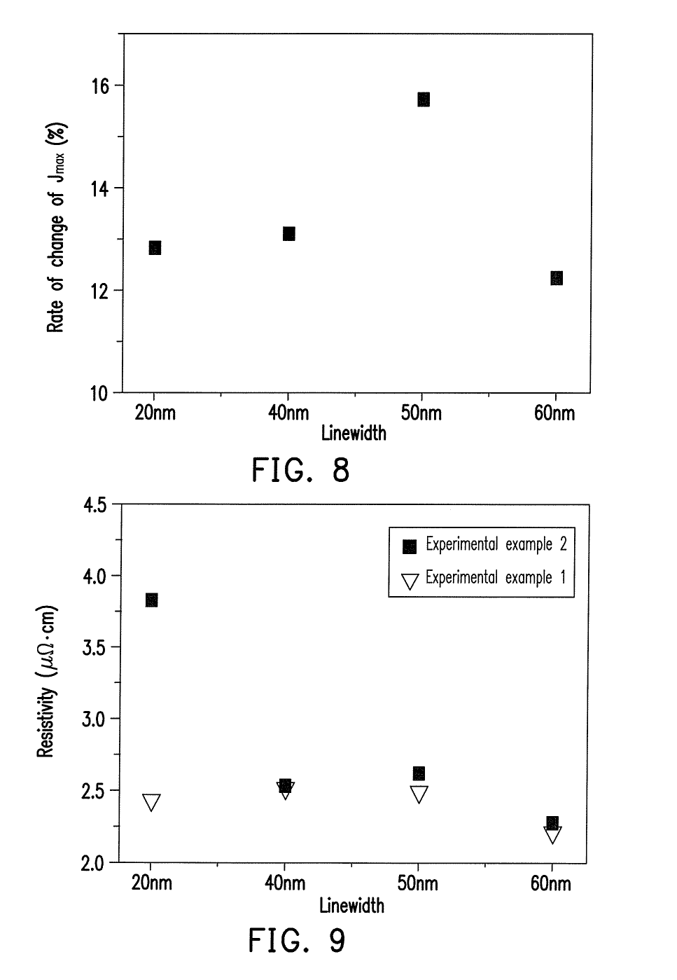

A current density test was repeatedly performed on the samples obtained in experimental example 1 and comparative example 1, and average values thereof were obtained. The results are shown in Table 3 and FIG. 7 below. At the same time, the rate of change of the difference in current density of experimental example 1 and comparative example 1 was calculated, and the results are shown in Table 3 and FIG. 8.

TABLE 3

| | | | Experimental |
|---|---|---|---|
| | Comparative | Experimental | example 1 |
| | example 1 | example 1 | Rate of change of |
| Linewidth | Average current density (MA/cm²) | | current density (%) |
| 20 nm | 282.0 | 318.2 | +12.8 |
| 40 nm | 220.5 | 249.4 | +13.1 |
| 50 nm | 192.1 | 222.2 | +15.7 |
| 60 nm | 192.0 | 215.5 | +12.2 |

It can be known from Table 3 and FIG. 8 that, at a linewidth of 20 nm to 60 nm, the current density of the semiconductor interconnect structures having a compound thin film is higher than that without compound thin film.

### Experimental Example 2

A compound thin film was grown on the surface of copper metal layers having different linewidths with the same steps as experimental example 1, but the surface of the substrate used in experimental example 2 was not covered and preserved by photoresist polymer.

### Comparative Example 2

A compound thin film was grown on the surface of copper metal layers having different linewidths using the same steps as preparation example 2, until the step in which H₂ plasma was introduced to perform pretreatment. Therefore, a compound thin film was absent in comparative example 2.

Test 5

A resistivity test was repeatedly performed on the samples obtained in experimental example 2 and comparative example 2, and average values thereof were obtained. The results are shown in Table 4 below. At the same time, the resistivity results of experimental example 1 and experimental example 2 are shown in FIG. 9.

TABLE 4

| | | |
|---|---|---|
| | | Experimental |
| Comparative | Experimental | example 2 |
| example 2 | example 2 | Rate of change of |

| | | |
|---|---|---|
| Linewidth | Average resistivity (μΩ · cm) | resistance (%) |

| | | | |
|---|---|---|---|
| 20 nm | 8.3 | 3.9 | −53.8 |
| 40 nm | 4.5 | 2.5 | −43.5 |
| 50 nm | 3.6 | 2.6 | −26.5 |
| 60 nm | 2.6 | 2.3 | −10.9 |

It can be known from Table 4 that, when the surface of the substrate is not covered and preserved by photoresist polymer, the compound thin film grown by the process of the invention can significantly reduce the resistivity thereof.

It can be known from FIG. 9 that, regardless of whether or not the substrate during preservation is covered by a polymer, the resistivity of the semiconductor interconnect structure after growing the compound thin film is reduced.

Test 6

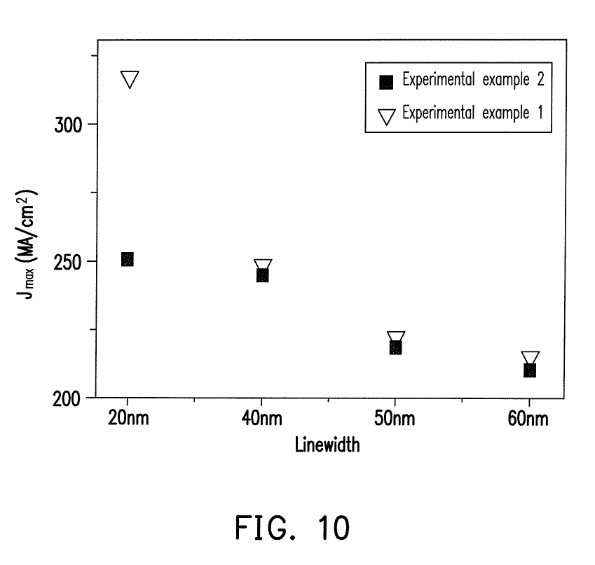

A current density test was repeatedly performed on the samples obtained in experimental example 2 and comparative example 2, and average values thereof were obtained. The results are shown in Table 5 below. At the same time, the current density results of experimental example 1 and experimental example 2 are shown in FIG. 10.

TABLE 5

| | | | Experimental |
|---|---|---|---|
| | Comparative | Experimental | example 2 |
| | example 2 | example 2 | Rate of change of |
| Linewidth | Average current density (MA/cm²) | | current density (%) |
| 20 nm | 121.4 | 251.3 | +107.0 |
| 40 nm | 158.3 | 244.9 | +54.7 |
| 50 nm | 177.8 | 218.2 | +22.7 |
| 60 nm | 198.7 | 210.4 | +5.8 |

It can be known from Table 5 that, when the surface of the substrate is not covered and preserved by a polymer, the compound thin film grown by the process of the invention can increase the current density thereof.

It can be known from FIG. 10 that, regardless of whether or not the substrate during preservation is covered by a polymer, the current density of the semiconductor interconnect structure after growing the compound thin film is increased.

Based on the above, in the invention, there is no need to grow graphene. As long as a compound thin film several atomic layers thick and containing organocopper and amorphous carbon is formed on the copper metal layer surface of the interconnect structure, interconnect resistivity can be reduced and current density can be increased, and these improvements are superior to those by forming graphene on the copper interconnect.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A semiconductor interconnect structure, comprising:
a barrier metal layer formed on an interconnect trench;
a copper metal layer formed on the barrier metal layer; and
a compound thin film formed on a surface of the copper metal layer, wherein the compound thin film contains organocopper and amorphous carbon.

2. The semiconductor interconnect structure of claim 1, wherein the organocopper of the compound thin film is formed by a carbon source via a plasma process.

3. The semiconductor interconnect structure of claim 1, wherein a structure of the organocopper of the compound thin film is a compound containing carbon and hydrogen or a compound containing carbon and copper bonds.

4. The semiconductor interconnect structure of claim 3, wherein the structure of the organocopper of the compound thin film comprises Cu—C2H2, Cu—CH3, Cu—C, or a non-stoichiometric Cu-CxHy, wherein 0<x≦2 and 0≦y≦3.

5. The semiconductor interconnect structure of claim 1, wherein the copper metal layer is pure copper or a copper alloy.

6. The semiconductor interconnect structure of claim 1, wherein the amorphous carbon of the compound thin film forms a partially crystalline structure after a heat treatment.

7. The semiconductor interconnect structure of claim 1, wherein a thickness of the compound thin film is from several atomic layers to tens of nanometers.

8. The semiconductor interconnect structure of claim 1, further comprising a dielectric layer, wherein the interconnect trench is formed within the dielectric layer, the copper metal layer is located within the interconnect trench, the surface of the copper metal layer is exposed from the dielectric layer, and the compound thin film is formed on the exposed surface of the copper metal layer.

9. The semiconductor interconnect structure of claim 8, further comprising a protective layer located on the compound thin film.

10. The semiconductor interconnect structure of claim 9, wherein the protective layer comprises a metal layer, an insulation layer, or a combination thereof.

11. A semiconductor interconnect structure, comprising:
a barrier metal layer formed on an interconnect trench;
a first copper metal layer formed on the barrier metal layer; and
a composite layer formed on a surface of the first copper metal layer, wherein the composite layer is formed with alternating compound thin films and second copper metal layers, and each of the compound thin films contains organocopper and amorphous carbon.

12. A manufacturing method of a semiconductor interconnect structure, comprising:
forming an interconnect trench structure;
forming a barrier metal layer on the interconnect trench structure;
forming a copper metal layer on the barrier metal layer; and
growing a compound thin film on a surface of the copper metal layer via a plasma-enhanced chemical vapor deposition method, wherein the compound thin film contains organocopper and amorphous carbon.

13. The method of claim 12, wherein a substrate temperature for growing the compound thin film is set to 450° C. or less.

14. The method of claim 12, wherein a reaction gas for growing the compound thin film comprises a carbon-containing gas, a hydrogen gas, and an inert gas.

15. The method of claim 14, wherein the carbon-containing gas comprises methane, ethylene, acetylene, or a combination thereof.

16. The method of claim 14, wherein the inert gas comprises argon, helium, or a combination thereof.

17. The method of claim 12, further comprising, before growing the compound thin film, performing a hydrogen plasma pretreatment on the copper metal layer.

18. The method of claim 12, further comprising, after growing the compound thin film, performing annealing in a hydrogen gas or a vacuum environment.

19. The method of claim 18, wherein a temperature for performing the annealing is 450° C. or less.
